(19) United States
(12) Patent Application Publication
(10) Pub. No.: US 2005/0269608 A1
(43) Pub. Date: Dec. 8, 2005

(54) Active pixel sensor with improved signal to noise ratio

(76) Inventor: Duk-min Yi, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/144,622

(22) Filed: Jun. 6, 2005

(30) Foreign Application Priority Data
Jun. 8, 2004 (KR) 2004-41859

(51) Int. Cl. H01L 31/062

(52) U.S. Cl. 257/292

(57) ABSTRACT

An active pixel sensor (APS) is disclosed which amplifies an electrical charge generated by a light-receiving unit using a charge amplification unit and thereafter processes an output current or voltage corresponding to an amplified version of the electrical charge. The light-receiving unit receives a light signal and generates holes and electrons corresponding to the received light signal, and the charge amplification unit receives and amplifies either the electrons or the holes.

### BACKGROUND OF THE INVENTION

1. Field of the Invention

The invention relates generally to an image sensor. More particularly, the invention relates to Active Pixel Sensor (APS) cells adapted for use in a Complementary Metal Oxide Semiconductor (CMOS) image sensor.

A claim of priority is made to Korean Patent Application No. 2004-41859 filed Jun. 8, 2004 in the Korean Intellectual Property Office, the disclosure of which is hereby incorporated by reference in its entirety.

2. Description of the Related Art

In general, a CMOS Image Sensor (hereinafter referred to as “CIS”) includes a number of APS cells, wherein each APS cell corresponds to an image pixel. Each APS cell receives light from an external source and transforms the received light into an electrical signal.

FIG. 1 is a circuit diagram illustrating the electrical functionality of a conventional APS cell. The APS cell shown in FIG. 1 includes a photo diode PD, charge transfer transistor M1, a reset transistor M2, a low selection transistor M3, a current transfer transistor M4, and a diffused capacitor C_{d}.

When photo diode PD is illuminated by a light signal, it absorbs photons from the received light signal and generates an electrical charge. Electrical charge is typically generated in the form of charge pairs comprising exited electrons and holes, but the term “electrical charge” is used throughout to denote charge pairs, electrons, or holes, respectively. In the illustrated example, the holes generated by photo diode PD tend to immediately drift to a (first) low power supply voltage (e.g., a ground (GND) potential) connected to a first end (e.g., the P-type electrode) of photo diode PD. Whereas, the electrons generated by photo diode PD tend to remain (i.e., an electrical charge of electrons is developed) in a second end (e.g., the N-type electrode) of photo diode PD, because the combination of charge transfer transistor M1 of photo diode PD under certain activation conditions form an energy barrier to the developed electrical charge.

In general, the energy barrier is sufficiently high to trap the electrons in photo diode PD near its second end (the N-type electrode). However, when a predetermined voltage V_{TG} is applied to the gate of charge transfer transistor M1, the charge transfer transistor M1 is turned ON, and the height of the energy barrier is reduced. In response to the reduced height of the energy barrier, the electrons generated by the photo diode PD can pass and move through charge transfer transistor M1.

A first end of reset transistor M2 is connected to a (second) high power supply voltage V_{DD} and a second end is connected to the second end of charge transfer transistor M1. When a reset signal V_{Reset} is applied to the gate of reset transistor M2, a voltage apparent at the second end of charge transfer transistor M1 transitions to a predetermined level.

The low-selection transistor M3 enables transfer of a voltage corresponding to the amount of charge generated by photo diode PD to the gate of current transfer transistor M4, and gates a supply current to current transfer transistors M4. That is, the high power supply voltage V_{DD} is connected to a first end of low-selection transistor M3, a second end of the low-selection transistor M3 is connected to a first end of current transfer transistor M4, and a low-select signal V_{RS} is used to gate the flow of current through low-selection transistor M3.

The gate of current transfer transistor M4 is commonly connected to the second end of charge transfer transistor M1 and the second end of reset transistor M2. A current Vₒᵤₜ corresponding to the voltage apparent at the gate of current transfer transistor M4 is output from a second end of current transfer transistor M4.

The diffused capacitor C_{d} illustrated in FIG. 1 is a floating capacitor apparent between the second end of charge transfer transistor M1 and a substrate (not shown) upon which the conventional APS cell is formed. The diffused capacitor C_{d} may be intentionally introduced in the circuit or be naturally generated during the manufacture of charge transfer transistor M1 and reset transistor M2. Where intentionally introduced, diffused capacitor C_{d} may be formed using a number of different manufacturing techniques. No matter how or why formed, however, the diffused capacitor C_{d} tends to trap or hold the electrons generated by photo diode PD.

In the foregoing manner, a photonic (e.g., light-related) signal is received and transformed into a corresponding electrical signal by the APS cell as shown in FIG. 1. Subsequently, the resulting electrical signal may be variously processed to produce image data indicative of the received photonic signal. Typically, a plurality of APS cells produce a corresponding array of pixilated image data. This array of image data may be variously manipulated and used to generate a visual image on a display. To improve the quality of the resulting visual image, the number of the APS cells may be increased. That is, the greater the number of pixels (and corresponding APS cells), the higher the resolution of the resulting visual image. However, unless the overall area of the constituent CIS is increased to accommodate more APS cells, improved visual image resolution requires a corresponding reduction in the size of the individual APS cells. Thus, given a defined or fixed CIS area, improved image quality requires an increased number of APS cells, and therefore a corresponding reduction in the size of the APS cells.

Reducing the area occupied by each APS cell necessarily requires a reduction in the size of the light-receiving portions of the individual APS cells, (hereinafter these portions of an APS cell will be referred to as “a light-receiving unit” regardless of their actual nature and composition). Unfortunately, as the area of the light-receiving unit is reduced, less light is received, and the number of resulting electrons decreases. This decrease in generated electrons lowers the overall efficiency of the transformation from externally provided light signal to an electrical signal. The weak electrical signal is characterized by a reduced signal to noise ratio, and the resulting image quality is reduced.

### SUMMARY OF THE INVENTION

The present invention provides an Active Pixel Sensor (APS) cell for a CIS, in which charges generated by a light-receiving unit having a relatively reduced surface area are amplified by a charge amplifier. In one embodiment, the APS cell comprises a light-receiving unit to receive a light signal and generate an electrical charge comprising electrons and holes in relation to received light signal. The APS cell also comprises a charge amplification unit to receive and amplify the electrons or holes generated by the light-receiving unit.

In a related embodiment, the light-receiving unit comprises at least one photo diode having a first end connected to a first power supply voltage and a second end connected to the charge amplification unit. In this regard, the first power supply voltage may be a high power supply voltage or a low power supply voltage in accordance with the overall design of the APS cell and its constituent element types.

In one related embodiment, the charge amplification unit comprises a bipolar transistor comprising a first end connected to a second power supply voltage, a base connected to the second end of the light-receiving unit, and a second end outputting a current corresponding to an amplified version of the electrons or holes received from the light-receiving unit. Here again, the second power supply voltage may be a high power supply voltage or a low power supply voltage as the overall design dictates.

In another embodiment, the APS cell further comprises a cell selection unit connected between the second power supply voltage and the charge amplification unit, the cell selection unit supplying current to the charge amplification unit in response to a low selection signal. The cell selection unit may comprise, for example, a MOS transistor having a first end connected to the second power supply voltage, a second end connected to the charge amplification unit, and a gate to which the low selection signal is applied.

In yet another embodiment, the APS cell further comprises a reset unit comprising a first end connected to a second end of the charge amplification unit, and a second end connected to a reset power supply voltage, the reset unit resetting an output of the charge amplification unit in response to a reset signal applied to the reset unit. The reset power supply voltage may be a low power supply voltage, a high power supply voltage, or a combination voltage of a low power supply voltage and a threshold voltage. The reset unit may comprise a MOS transistor comprising a first end connected to the reset power supply voltage and a gate to which the reset signal is applied.

In yet another embodiment, the APS cell further comprises a charge transfer unit connected between the light-receiving unit and the charge amplification unit, and transferring electrons or holes from the light-receiving unit to the charge amplification unit in response to a charge transfer signal. The charge transfer unit may comprise a MOS transistor having a first end connected to the light-receiving unit, a second end connected to the charge amplification unit, and a gate to which the charge transfer signal is applied.

In another related embodiment, the light-receiving unit comprises a plurality of light-receiving units. Similarly, the charge transfer unit may comprise a plurality of charge transfer devices responsive to a plurality of control signals to transmit electrons or holes generated by a respective one of the plurality of light-receiving unit. Each one of the plurality of light-receiving units may comprise a photo diode, and each one of the plurality of charge transfer unit devices may comprise a MOS transistor.

Various P-type and N-type devices and/or circuits may be used to implement the charge amplification unit, the cell selection unit, the charge transfer unit, the reset unit and a related current transfer unit. Corresponding power supply selections may be made in relation to the design choices for elements implementing the foregoing.

### BRIEF DESCRIPTION OF THE DRAWINGS

The invention will be further described hereafter in relation to several exemplary embodiments with reference to the accompanying drawings. Throughout the drawings, like reference number indicate like elements. Within the drawings:

FIG. 1 is a circuit diagram of a conventional Active Pixel Sensor (APS) cell;

FIG. 2 is a block diagram of an APS cell according to an embodiment of the present invention;

FIG. 3 is a detailed block diagram of the APS cell of FIG. 2;

FIG. 4 is a block diagram of an APS cell according to another embodiment of the present invention;

FIG. 5 is a detailed block diagram of the APS cell of FIG. 4;

FIG. 6 is a circuit diagram of an APS cell according to an embodiment of the present invention;

FIG. 7 is a circuit diagram of an APS cell according to another embodiment of the present invention;

FIG. 8 is a circuit diagram of an APS cell according to yet another embodiment of the present invention;

FIG. 9 is a circuit diagram of an APS cell according to still another embodiment of the present invention;

FIG. 10 is a circuit diagram of an APS cell according to an embodiment of the present invention; and

FIG. 11 is a circuit diagram of an APS cell according to another embodiment of the present invention.

### DETAILED DESCRIPTION OF THE INVENTION

In one aspect, the invention addresses the need for improved image quality from a CMOS Image Sensor (CIS) having smaller sized Active Pixel Sensor (APS) cells. That is, APS cells with reduced overall size allow the implementation of a CIS having a denser array of pixels. A denser array of pixels will provide improved image resolution—provided the signal to noise ratio for electrical signals resulting from the conversion of a received light signal remains sufficiently high. Thus, in another aspect, the invention provides an APS cell adapted to output an electrical signal having a high signal to noise ratio.

To recap some of the foregoing discussion, an APS cell generates electrons and holes in light-receiving unit, such as a photo diode, which receives an externally supplied light signal. The “light signal” received by the light-receiving unit may include one or more signals selected from the entire electromagnetic spectrum. More particularly, the light signal may include one or more signals having a visible light wavelength, or an infrared (or near-infrared) wavelength. Within the APS cell, the electrons generated by the light-receiving unit are transmitted to a diffused capacitor via a charge transfer transistor, and change a voltage apparent at a gate of a current transfer transistor.

The multiple embodiments that follow are shown in forms and examples that communicate the making and use of the invention. However, all of the elements illustrated and described in relation to various embodiments should not be deemed somehow essential or mandatory to the invention. For example, a separate cell selection unit, a charge transfer unit, a reset unit, and a current transfer unit may be beneficially included or omitted from a given design.

In view of the foregoing, one embodiment of the invention provides an improved APS cell in which electrons or holes generated by a light-receiving unit are amplified before being applied to the gate of a current transfer transistor, thereby improving a signal to noise ratio. FIG. 2 is a block diagram illustrating this embodiment of an APS cell according to the invention. The exemplary APS cell of FIG. 2 generally includes a light-receiving unit 210 and a charge amplification unit 220. The exemplary APS cell may also include a cell selection unit 230. The term “unit” as used throughout this description should be broadly construed to mean a circuit, a circuit portion, a circuit element, an electrical device, an optical device, and/or an electro-optical device.

Light-receiving unit 210 receives a light signal and generates charge pairs of electrons and holes. Charge pairs are generally produced in light-receiving unit 210 in proportion to the quantity of photons illuminating the unit from the received light signal. Hence, a light-receiving unit of relatively smaller size receives less light, fewer photons, and accordingly generates fewer charge pairs. Nonetheless, charge amplification unit 220 receives and amplifies either the electrons or the holes generated by light-receiving unit 210. Cell selection unit 230 supplies a current received from a power supply voltage V_{DD} to charge amplification unit 220 in response to a low selection signal V_{RS} that controls operation of the APS cell.

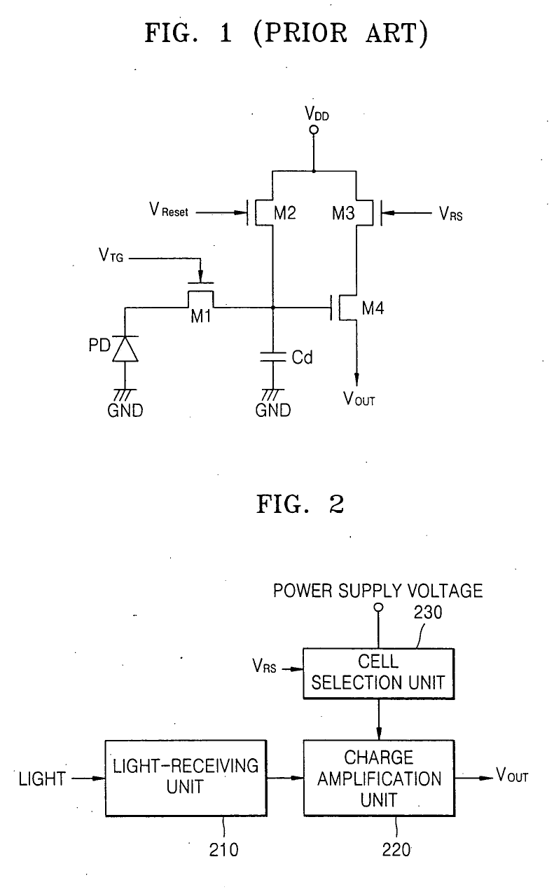

Charge amplification unit 220 may be adapted to amplify electrons or holes either of which may be transmitted to charge amplification unit 220 from light-receiving unit 210. The charge type to be transferred is selected in accordance with the type of voltage source connected to light-receiving unit 210. For example, when light-receiving unit 210 comprises a photo diode and a low power supply voltage (e.g., GND) is connected to a P-type electrode of light-receiving unit 210, the holes generated by light-receiving unit 210 will move toward the low power supply voltage. As a further result, the electrons generated by light-receiving unit 210 are transferred to charge amplification unit 220. The foregoing may be accomplished, for example, using a circuit generally consistent with the circuit described above in relation to FIG. 1. However, provision must be made within this context to amplify the electrons generated by light-receiving unit 210.

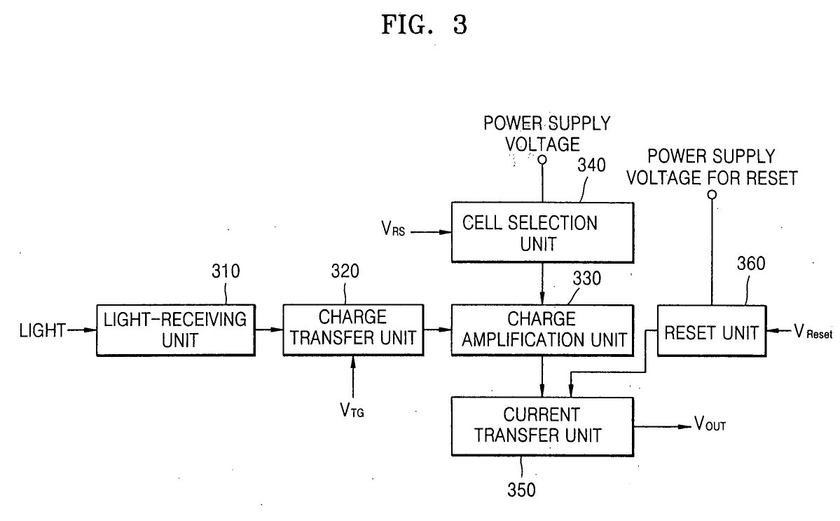

FIG. 3 is a detailed block diagram showing the APS cell of FIG. 2 in some additional detail. The APS cell of FIG. 3 includes a light-receiving unit 310, a charge transfer unit 320, a charge amplification unit 330, a cell selection unit 340, a current transfer unit 350, and a reset unit 360.

Light-receiving unit 310 receives a light signal and generates charges, i.e., holes and electrons, corresponding to the received light signal. Charge transfer unit 320 transmits either electrons or holes to charge amplification unit 330 in response to charge transfer signal V_{TG}. Charge amplification unit 330 receives and amplifies the transferred charges generated by light-receiving unit 310. Cell selection unit 340 supplies a current provided from power supply voltage V_{DD} to charge amplification unit 330 in response to low selection signal V_{RS}. In effect, low selection signal V_{RS} determines when the APS cell is selected for operation. Current transfer unit 350 outputs a current corresponding to the transferred charges amplified by charge amplification unit 330 when the APS cell is selected in response to the low selection signal V_{RS}.

Reset unit 360 resets the output of current transfer unit 350 to a predetermined value in response to reset signal V_{Reset}. A Reset power supply voltage is connected to reset unit 360 and is preferably either a high-level power supply voltage or a low-level power supply voltage apparent within the APS cell. Alternatively, the Reset power supply voltage may be some voltage combination of the low power supply voltage and a threshold voltage for a MOS transistor. The actual type of Reset power supply voltage used will be determined in accordance with the type of bipolar transistor and/or MOS transistor used by the APS cell, as well as the value of an output voltage from charge amplification unit 330.

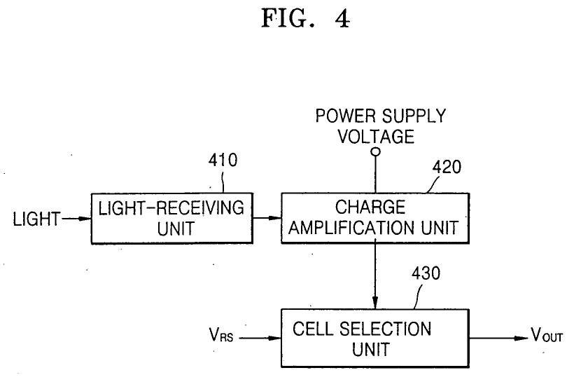

FIG. 4 is a block diagram of an APS cell according to another embodiment of the invention. The APS cell of FIG. 4 comprises a light-receiving unit 410 and a charge transfer unit 420, and may further include a cell selection unit 430.

Light-receiving unit 410 receives a light signal and generates charge pairs in accordance with the received light signal. Charge amplification unit 420 receives either electrons or holes from light-receiving unit 410 and amplifies them using a power supply voltage V_{DD}. Cell selection unit 430 transmits the charges amplified by charge amplification unit 420 in response to low selection signal V_{RS}.

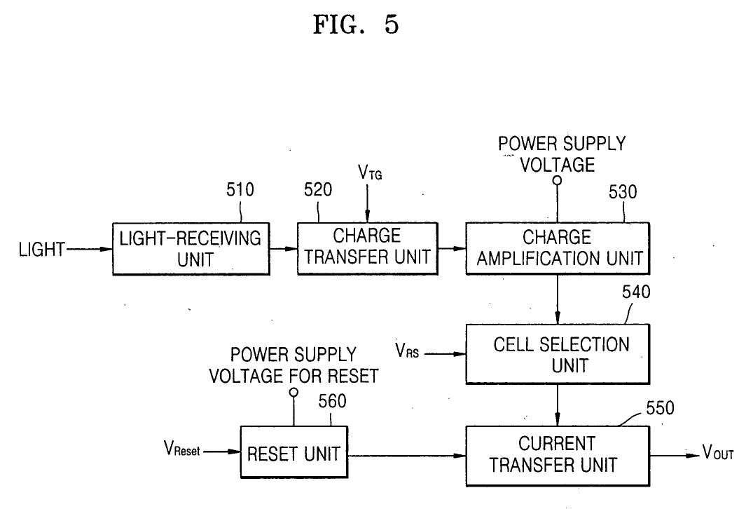

FIG. 5 is a block diagram illustrating the APS cell of FIG. 4 in some additional detail. The APS cell of FIG. 5 includes a light-receiving unit 510, a charge transfer unit 520, a charge amplification unit 530, a cell selection unit 540, a current transfer unit 550, and a reset unit 560.

Light-receiving unit 510 receives a light signal and generates charges corresponding to the received light signal. Charge transfer unit 520 transmits either electrons or holes generated by light-receiving unit 510 to charge amplification unit 530 in response to charge transfer signal V_{TG}. Charge amplification unit 530 amplifies the received charges using a power supply voltage V_{DD}. Cell selection unit 540 transmits the amplified charges to current transfer unit 550 in response to low selection signal V_{RS}. Current transfer unit 550 outputs a current corresponding to the charges when the APS cell is selected in response to low selection signal V_{RS}.

Reset unit 560 resets the output of current transfer unit 550 to a predetermined value in response to reset signal V_{Reset}. A reset power supply voltage is used by reset unit 560 may be a high-level power supply voltage or a low power supply voltage apparent within the APS cell. Alternatively, the reset power supply voltage may be a voltage combination of the low power supply voltage and a threshold voltage for a MOS transistor. The type of reset power supply voltage is determined in relation to the type of bipolar transistor and/or MOS transistor used within the APS cell, and in relation to the output of charge amplification unit 330.

In one embodiment of the application, charges pairs generated by light-receiving units 210, 310, 410, and 510 include electrons and holes, however, charge amplification units 220, 330, 420, and 530 generally amplify either electrons or holes.

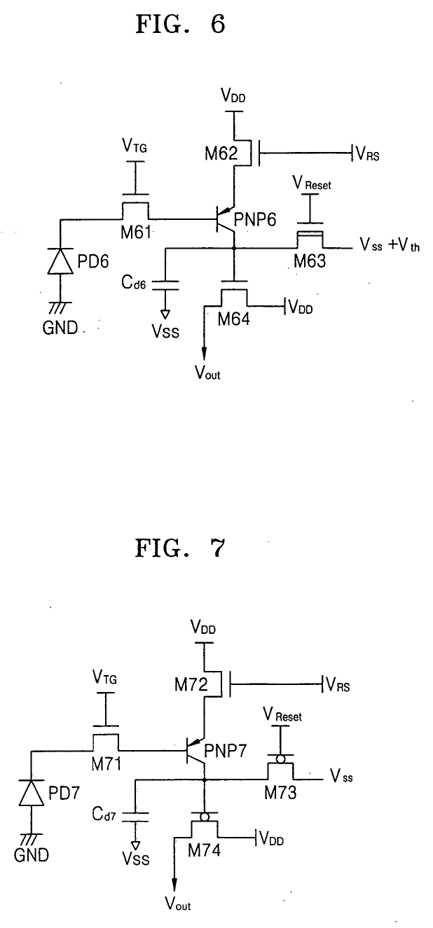

Additional embodiments of APS cells according to the invention will now be described with reference to the exemplary circuits illustrated in FIGS. 6 through 11. These specific circuits are described in the context of selected exemplary current transfer transistors M64, M74, M84, M94, M104, and M114 and diffused capacitors C_{d6} through C_{d11} as shown in FIGS. 6 through 11. However, the invention is not limited to the teaching examples described herein. Those of ordinary skill in the art will recognize that APS cells according to embodiments of the invention may be variously constructed.

FIG. 6 is a circuit diagram of an APS cell according to one embodiment of the invention. The APS cell of FIG. 6 includes a photo diode PD6, an N-type charge transfer MOS transistor M61, an N-type charge selection MOS transistor M62, a PNP-type charge amplification bipolar transistor PNP6, an N-type reset MOS transistor M63, an N-type current transfer MOS transistor M64, and a diffused capacitor C_{d6}.

A low power supply (GND) is connected to the P-type electrode of photo diode PD6, and upon receiving a light signal, charge pairs are generated in photo diode PD6. Electrons from these charge pairs tend to collect near the N-type electrode of photo diode PD6. A first end of N-type charge transfer MOS transistor M61 is connected to the N-type electrode of photo diode PD6, and a charge transfer signal V_{TG} is applied to a gate of N-type charge transfer MOS transistor M61. A high-level power supply voltage V_{DD} is connected to N-type cell selection MOS transistor M62, and a low selection signal V_{RS} is applied to the gate of N-type cell selection MOS transistor M62. A first end of PNP-type charge amplification bipolar transistor PNP6 is connected to a second end of the N-type cell selection MOS transistor M62, and it's base is connected to the second end of N-type charge transfer MOS transistor M61. N-type reset MOS transistor M63 is a depletion transistor, a first end of which is connected to a power supply source with a voltage equal to a voltage V_{SS}+Vₜₕ, which is a voltage combination of low power supply voltage V_{SS} and a threshold voltage Vₜₕ. A second end of reset MOS transistor M63 is connected to the second end of PNP-type charge amplification bipolar transistor PNP6. A reset signal V_{Reset} is applied to a gate of N-type MOS transistor M63. The low power supply voltage V_{SS} may be equal to or less than a ground voltage GND.

A high-level power supply voltage V_{DD} is connected to a first end of N-type current transfer MOS transistor M64, which outputs a current when the voltage apparent at the second end of PNP-type charge amplification bipolar transistor PNP6 is applied to the gate of N-type MOS transistor M64. The voltage corresponding to the output current is determined by an additional circuit (not shown) connected to the second end of N-type current transfer MOS transistor M64. A diffused capacitor C_{d6} may be provided by the intentional application of one of a number of conventional manufacturing techniques. However, instead of intentionally manufacturing the diffused capacitor C_{d6}, a naturally occurring parasitic capacitor at an overlapped area between drain/source electrodes and gate electrode may be used as the diffused capacitor C_{d6}.

The structure and operation of N-type current transfer MOS transistor M64 and diffused capacitor C_{d6} are the same as those of N-type MOS transistors for current transfer M74, M84, M94, M104, and M114 and diffused capacitors C_{d7}, C_{d8}, C_{d9}, C_{d10}, and C_{d11} of FIGS. 7 through 11. Therefore, specific descriptions related to these elements will be omitted for the sake of brevity.

FIG. 7 is a circuit diagram of an APS cell according to another embodiment of the invention. The APS cell of FIG. 7 includes a photo diode PD7, an N-type current transfer MOS transistor M71, an N-type cell selection MOS transistor M72, a PNP-type charge amplification bipolar transistor PNP7, a P-type reset MOS transistor M73, a P-type MOS transistor for current transfer M74, and a diffused capacitor C_{d7}.

A low power supply voltage (GND) is connected to a P-type electrode of photo diode PD7, and an N-type electrode of photo diode PD7 receives a light signal and generates charges corresponding to the received light signal. A first end of N-type charge transfer MOS transistor M71 is connected to the N-type electrode of photo diode PD7 and a charge transfer signal V_{TG} is applied to the gate of N-type charge transfer MOS transistor M71. A high-level power supply voltage V_{DD} is connected to a first end of the N-type cell selection MOS transistor M72 and a low selection signal V_{RS} is applied to the gate of N-type cell selection MOS transistor M72. A first end of PNP-type charge amplification bipolar transistor PNP7 is connected to a second end of N-type cell selection MOS transistor M72 and its base is connected to a second end of N-type charge transfer MOS transistor M71. The low power supply voltage (GND) is connected to a first end of P-type reset MOS transistor M73, a second end of P-type reset MOS transistor M73 is connected to the second end of PNP-type charge amplification bipolar transistor PNP7, and a reset signal V_{Reset} is applied to the gate of P-type reset MOS transistor M73.

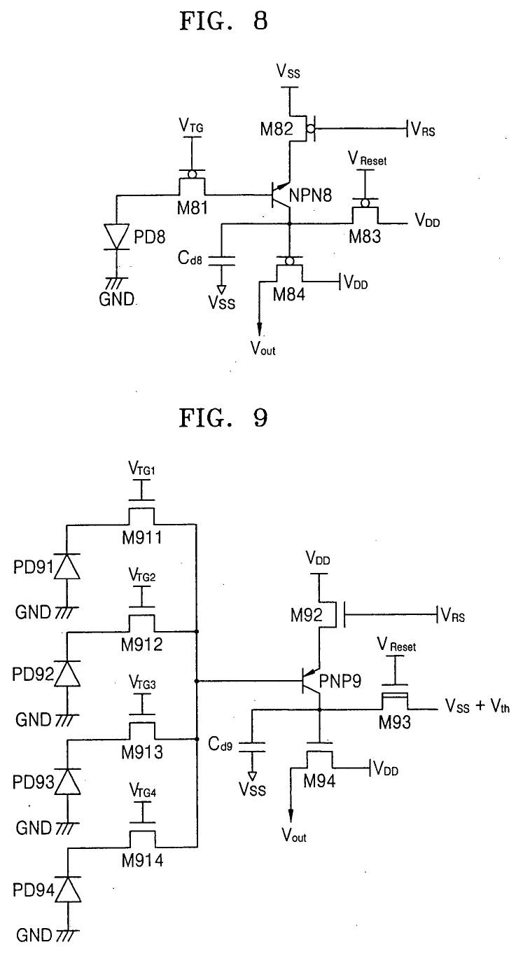

FIG. 8 is a circuit diagram of an APS cell according to yet another embodiment of the invention. The APS cell of FIG. 8 includes a photo diode PD8, a P-type charge transfer MOS transistor M81, a P-type cell selection MOS transistor M82, an NPN-type charge amplification bipolar transistor NPN8, a P-type reset MOS transistor M83, a P-type current transfer MOS transistor M84, and a diffused capacitor C_{d8}.

A low power supply voltage (GND) is connected to an N-type electrode of photo diode PD8, and its P-type electrode receives a light signal and generates charges corresponding to the received light signal. A first end of P-type charge transfer MOS transistor M81 is connected to the P-type electrode of photo diode PD8 and a charge transfer signal V_{TG} is applied to the gate of P-type charge transfer MOS transistor M81. The low power supply voltage (GND) is connected to a first end of P-type cell selection MOS transistor M82 and a low selection signal V_{RS} is applied to the gate of P-type cell selection MOS transistor M82. A first end of NPN-type charge amplification bipolar transistor NPN8 is connected to a second end of P-type cell selection MOS transistor M82 and its base is connected to the second end of P-type charge transfer MOS transistor M81. A high-level power supply voltage V_{DD} is connected to P-type reset MOS transistor M83, the second end is connected to the second end of NPN-type charge amplification bipolar transistor NPN8, and a reset signal V_{Reset} is applied to the gate of P-type reset MOS transistor M83.

FIG. 9 is a circuit diagram of an APS cell according to still another embodiment of the invention. The APS cell of FIG. 9 includes a plurality of photo diodes PD91 through PD94, a plurality of N-type charge transfer MOS transistors M911 through M914, an N-type cell selection MOS transistor M92, a PNP-type charge amplification bipolar transistor PNP9, an N-type reset MOS transistor M93, an N-type current transfer MOS transistor M94, and a diffused capacitor C_{d9}.

A low power supply voltage (GND) is connected to P-type electrodes of the plurality of photo diodes PD91 through PD94, and their respective N-type electrodes receive respective light signals and generate charges corresponding to the received light signals. First ends of the respective N-type charge transfer MOS transistors M911 through M914 are connected to a corresponding N-type electrode from one of the plurality of photo diodes PD91 through PD94. Corresponding charge transfer signals V_{TG1} through V_{TG4} are applied to the respective gates of the plurality of N-type charge transfer MOS transistors M911 through M914.

The relationship between the plurality of photo diodes PD91 through PD94 and the plurality of N-type charge transfer MOS transistors M911 through M914 will now be described in some additional detail. In the illustrated example, photo diode PD91 is connected to N-type charge transfer MOS transistor M911. The other photo diodes PD92 through PD94 are respectively connected to N-type charge transfer MOS transistors M912 through M914.

A high-level power supply voltage V_{DD} is connected to a first end of N-type cell selection MOS transistor M92 and a low selection signal V_{RS} is applied to the gate of N-type cell selection MOS transistor M92. A first end of PNP-type charge amplification bipolar transistor PNP9 is connected to the second end of N-type cell selection MOS transistor M92, and its base is commonly connected to each one of the plurality of N-type charge transfer MOS transistors M911 through M914. N-type reset MOS transistor M93 is a depletion transistor, a first end of which is connected to a power supply source having a voltage (V_{SS}+Vₜₕ) equal to a combination of low power supply voltage V_{SS} and a threshold voltage Vₜₕ. The second end of N-type reset MOS transistor M93 is connected to the second end of PNP-type charge amplification bipolar transistor PNP9. A reset voltage V_{Reset} is applied to the gate of N-type reset MOS transistor M93.

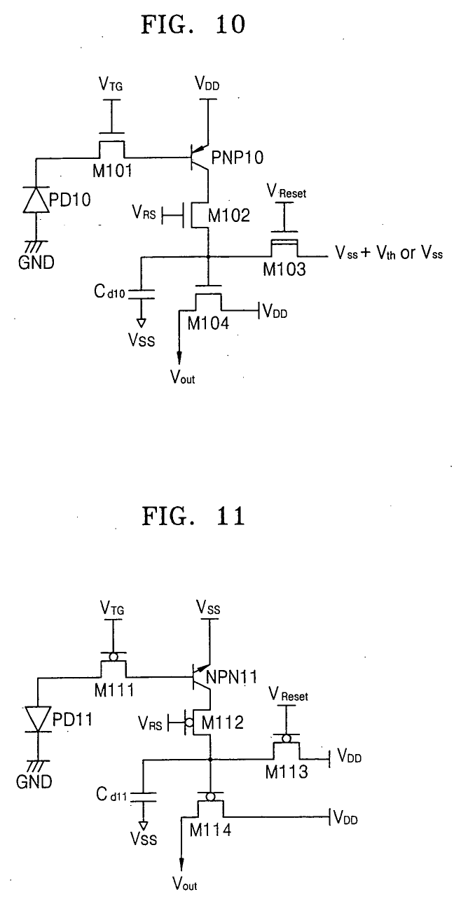

FIG. 10 is a circuit diagram of an APS cell according to an still another embodiment of the invention. The APS cell of FIG. 10 includes a photo diode PD10, an N-type charge transfer MOS transistor M101, an N-type cell selection MOS transistor M102, a PNP-type charge amplification bipolar transistor PNP10, an N-type reset MOS transistor M103, an N-type charge transfer MOS transistor M104, and a diffused capacitor C_{d10}.

A low power supply voltage (GND) is connected to a P-type electrode of the photo diode PD10, and its N-type electrode receives a light signal and generates charges corresponding to the received light signal. A first end of the N-type charge transfer MOS transistor M101 is connected to the N-type electrode of photo diode PD10, and a charge transfer signal V_{TG} is applied to the gate of N-type charge transfer MOS transistor M101. A high-level power supply voltage V_{DD} is connected to a first end of PNP-type charge amplification bipolar transistor PNP10 and its base is connected to the second end of N-type charge transfer MOS transistor M101. A first end of N-type cell selection MOS transistor M102 is connected to the second end of PNP-type charge amplification bipolar transistor PNP10, and a low selection signal V_{RS} is applied to the gate of N-type cell selection MOS transistor M102. N-type reset MOS transistor M103 is a depletion transistor, a first end of which is connected to a power supply source whose a voltage (V_{SS}+Vₜₕ) is equal to a voltage combination of low power supply voltage V_{SS} and threshold voltage Vₜₕ. The second end of N-type reset MOS transistor M103 is connected to the second end of N-type cell selection MOS transistor M102. A reset signal V_{Reset} is applied to the gate of N-type reset MOS transistor M103.

FIG. 11 is a circuit diagram of an APS cell according to another embodiment of the present invention. The APS cell of FIG. 11 includes a photo diode PD11, a P-type charge transfer MOS transistor M111, an NPN-type charge amplification bipolar transistor NPN11, a P-type cell selection MOS transistor M112, a P-type reset MOS transistor M113, a P-type current transfer MOS transistor M114, and a diffused capacitor C_{d11}.

A low power supply voltage (GND) is connected to an N-type electrode of photo diode PD11, and a P-type electrode of the photo diode PD11 receives a light signal and generates charges corresponding to the received light signal. A first end of P-type charge transfer MOS transistor M111 is connected to the P-type electrode of photo diode PD11, and a charge transfer signal V_{TG} is applied to the gate of P-type charge transfer MOS transistor M111. The low power supply voltage (GND) is connected to a first end of NPN-type charge amplification bipolar transistor NPN11 and the base of NPN-type charge amplification bipolar transistor NPN11 is connected to the second end of P-type charge transfer MOS transistor M111. A first end of P-type cell selection MOS transistor M112 is connected to the second end of NPN-type charge amplification bipolar transistor NPN11 and a low selection signal V_{RS} is applied to the gate of P-type cell selection MOS transistor M112. A high power supply voltage V_{DD} is connected to a first end of P-type reset MOS transistor M113, a second end of the P-type reset MOS transistor M113 is connected to the second end of the P-type MOS transistor for cell selection M112, and a reset signal V_{Reset} is applied to the gate of P-type reset MOS transistor M113.

As variously described above in the foregoing embodiments, an APS cell according to the invention generates charges in a light-receiving unit in response to a received light signal. These charges are then amplified in a charge amplification unit to thereby improve the signal to noise ratio of a resulting electrical signal. Accordingly, even if the surface area of individual light-receiving units is reduced to increase the number of light-receiving units associated with an image sensor of defined size, the image ultimately derived from the output of the constituent light-receiving units either remains high or may actually be improved. That is, the invention provides in one embodiment a light-receiving unit of reduced relative size which output an electrical signal having high signal to noise ratio.

The invention has been particularly shown and described with reference to exemplary teaching embodiments. It will be understood by those skilled in the art that various changes in form and details may be made therein without departing from the scope of the invention which is defined by the appended claims.

1. An active pixel sensor, comprising:
a light-receiving unit to receive a light signal and generate an electrical charge comprising electrons and holes in relation to the received light signal; and
a charge amplification unit to receive and amplify the electrons or holes generated by the light-receiving unit.

2. The active pixel sensor of claim 1, wherein the light-receiving unit comprises at least one photo diode having a first end connected to a first power supply voltage and a second end connected to the charge amplification unit.

3. The active pixel sensor of claim 2, wherein the first power supply voltage is a high power supply voltage or a low power supply voltage.

4. The active pixel sensor of claim 2, wherein the charge amplification unit comprises a bipolar transistor comprising:
a first end connected to a second power supply voltage;
a base connected to the second end of the light-receiving unit; and,
a second end outputting a current corresponding to an amplified version of the electrons or holes received from the light-receiving unit.

5. The active pixel sensor of claim 4, wherein the second power supply voltage is a high power supply voltage or a low power supply voltage.

6. The active pixel sensor of claim 5, further comprising:
a cell selection unit connected between the second power supply voltage and the charge amplification unit, the cell selection unit supplying current to the charge amplification unit in response to a low selection signal.

7. The active pixel sensor of claim 6, wherein the cell selection unit comprises:
a MOS transistor having a first end connected to the second power supply voltage, a second end connected to the charge amplification unit, and a gate to which the low selection signal is applied.

8. The active pixel sensor of claim 6, further comprising:
a reset unit comprising a first end connected to a second end of the bipolar transistor and a second end connected to a reset power supply voltage, the reset unit resetting an output of the charge amplification unit in response to a reset signal applied to the reset unit.

9. The active pixel sensor of claim 8, wherein the reset power supply voltage is a low power supply voltage, a high power supply voltage, or a combination voltage of a low power supply voltage and a threshold voltage.

10. The active pixel sensor of claim 9, wherein the reset unit comprises a MOS transistor comprising a first end connected to the reset power supply voltage and a gate to which the reset signal is applied.

11. The active pixel sensor of claim 6, further comprising:
a charge transfer unit connected between the light-receiving unit and the charge amplification unit, and transferring electrons or holes from the light-receiving unit to the charge amplification unit in response to a charge transfer signal.

12. The active pixel sensor of claim 11, wherein the charge transfer unit comprises a MOS transistor having a first end connected to the light-receiving unit, a second end connected to the charge amplification unit, and a gate to which the charge transfer signal is applied.

13. The active pixel sensor of claim 6, wherein the light-receiving unit comprises a plurality of light-receiving units; and,
the charge transfer unit comprises a plurality of charge transfer devices responsive to a plurality of control signals to each transmit electrons or holes generated by a respective one of the plurality of light-receiving units.

14. The active pixel sensor of claim 13, wherein each one of the plurality of light-receiving units comprises a photo diode, and
wherein each of the plurality of charge transfer unit devices comprises a MOS transistor.

15. An active pixel sensor, comprising:
a light-receiving unit to receive a light signal and generate an electrical charge comprising electrons and holes in relation to the received light signal; and
a charge amplification unit to receive and amplify either the electrons or holes generated by the light-receiving unit, the charge amplification unit being connected to a first power supply voltage and outputting a current or a voltage in relation to an amplified version of the received electrons or holes.

16. The active pixel sensor of claim 15, wherein the light-receiving unit comprises at least one photo diode having a first end connected to a second power supply voltage and a second end connected to the charge amplification unit, wherein the second power supply voltage is a high power supply voltage or a low power supply voltage selected in accordance with the type of elements comprising the active pixel sensor cell.

17. The active pixel sensor of claim 15, wherein the charge amplification unit comprises a bipolar transistor comprising:
a first end connected to the first power supply voltage;
a base connected to the light-receiving unit; and,
a second end outputting a current corresponding to an amplified version of the holes or electrons; and,
wherein the first power supply voltage is a high power supply voltage or a low power supply voltage selected in accordance with the type of elements comprising the active pixel sensor cell.

18. The active pixel sensor of claim 15, further comprising:
a cell selection unit receiving the current from the charge amplification unit and supplying the current in response to a low selection signal.

19. The active pixel sensor of claim 18, wherein the cell selection unit comprises a MOS transistor having a first end connected to the charge amplification unit and a gate to which the low selection signal is applied.

20. The active pixel sensor of claim 18, further comprising:
a reset unit including a first end connected to a second end of the charge amplification unit and a second end connected to a reset power supply voltage, the reset unit resetting an output of the charge amplification unit in response to a predetermined reset signal,
wherein the reset power supply voltage is a low power supply voltage, a high power supply voltage, or a voltage combination of a low power supply voltage and a threshold voltage selected in accordance with the type of element comprising the charge amplification unit or the type of element comprising the reset unit.

21. The active pixel sensor of claim 20, wherein the reset unit comprises a MOS transistor comprising a first end connected to the reset power supply voltage a gate to which the reset signal is applied.

22. The active pixel sensor of claim 20, further comprising:
a charge transfer unit connected between the light-receiving unit and the charge amplification unit, the charge transfer unit transmitting the holes or electrons generated by the light-receiving unit to the charge amplification unit in response to a charge transfer signal.

23. The active pixel sensor of claim 22, wherein the charge transfer unit comprises a MOS transistor comprising a first end connected to the light-receiving unit, a second end connected to the charge amplification unit, and a gate to which the charge transfer signal is applied.

24. The active pixel sensor of claim 22, wherein the light-receiving unit comprises a plurality of light-receiving units; and,
the charge transfer unit comprises a plurality of charge transfer units operating in response to the plurality of control signals, each one of the charge transfer units being connected to a respective one of the light-receiving unit devices.

25. The active pixel sensor of claim 24, wherein each one of the plurality of light-receiving unit devices comprises a photo diode; and,
wherein each one of the charge transfer units comprises a MOS transistor.

26. An active pixel sensor to receive an externally provided light signal and generate a current or voltage signal corresponding to the received light signal, comprising:
a photo diode comprising a P-type electrode connected to a first low power supply voltage and an N-type electrode developing an electrical charge in response to the received light signal;
an N-type charge transfer MOS transistor comprising a first end connected to the N-type electrode of the photo diode and a gate to which a charge transfer signal is applied;
an N-type cell selection MOS transistor comprising a first end connected to a high power supply voltage and a gate to which a low selection signal is applied;
a PNP-type charge amplification bipolar transistor comprising a first end connected to a second end of the N-type charge transfer MOS transistor and a base connected to a second end of the N-type cell selection MOS transistor; and
an N-type reset MOS transistor comprising a first end connected to a power supply terminal providing a voltage equal to a combination of a threshold voltage and one selected from a group consisting of the first low power supply voltage and a second low power supply voltage, a second end connected to a second end of the PNP-type charge amplification bipolar transistor, and a gate to which a reset signal is applied.

27. The active pixel sensor of claim 26, wherein the N-type reset MOS transistor is an N-type depletion MOS transistor.

28. An active pixel sensor to receive an externally provided light signal and generate a current or voltage signal corresponding to the received light signal, comprising:
a photo diode comprising a P-type electrode connected to a low power supply voltage and an N-type electrode developing an electrical charge in response to the received light signal;
an N-type charge transfer MOS transistor comprising a first end connected to the N-type electrode of the photo diode and a gate to which a charge transfer signal is applied;
an N-type cell selection MOS transistor comprising a first end connected to a high power supply voltage and a gate to which a low selection signal is applied;
a PNP-type charge amplification bipolar transistor comprising a first end connected to a second end of the N-type cell selection MOS transistor and a base connected to a second end of the N-type charge transfer MOS transistor; and
a P-type reset MOS transistor comprising a first end connected to a low power supply voltage, a second end connected to a second end of the PNP-type charge amplification bipolar transistor, and a gate to which a reset signal is applied.

29. An active pixel sensor to receive an externally provided light signal and generate a current or a voltage signal corresponding to the received light signal, comprising:
a photo diode comprising an N-type electrode connected to a low power supply voltage and a P-type electrode developing an electrical charge in response to the received light signal;
a P-type charge transfer MOS transistor comprising a first end connected to the P-type electrode of the photo diode and a gate to which a charge transfer signal is applied;
a P-type cell selection MOS transistor comprising a first end connected to a low power supply voltage and a gate to which a low selection signal is applied;
a PNP-type charge amplification bipolar transistor comprising a first end connected to a second end of the P-type cell selection MOS transistor and a base connected to a second end of the P-type charge transfer MOS transistor; and
a P-type reset MOS transistor comprising a first end connected to a high power supply voltage, a second end connected to a second end of the PNP-type charge amplification bipolar transistor, and a gate to which a reset signal is applied.

30. An active pixel sensor to receive an externally provided light signal and generate a current or voltage signal in response to the received light signal, comprising:
a plurality of photo diodes, each photo diode comprising a P-type electrode connected to a first low power supply voltage and an N-type electrode developing an electrical charge in response to the received light signal;
a plurality of N-type MOS transistors to transfer charge, each N-type MOS transistor comprising a first end connected to the N-type electrode of a corresponding photo diode and a gate to which a corresponding charge transfer signal is applied;
an N-type cell selection MOS transistor comprising a first end connected to a high power supply voltage and a gate to which a low selection signal is applied;
a PNP-type charge amplification bipolar transistor comprising a first end connected to a second end of the N-type cell selection MOS transistor and a base connected to a second end of each of the N-type charge transfer MOS transistors; and
an N-type reset MOS transistor comprising a first end connected to a power supply terminal providing a voltage equal to a combination of a threshold voltage and one selected from a group consisting of the first low power supply voltage and a second low power supply voltage, a second end connected to a second end of the PNP-type charge amplification bipolar transistor, and a gate to which a reset signal is applied.

31. The active pixel sensor of claim 30, wherein the N-type reset MOS transistor is an N-type depletion MOS transistor.

32. An active pixel sensor to receive an externally provided light signal and generate a current or a voltage signal in response to the received light signal, comprising:
a photo diode comprising a P-type electrode connected to a low power supply voltage and an N-type electrode developing an electrical charge in response to the received light signal;
an N-type charge transfer MOS transistor comprising a first end connected to the N-type electrode of the photo diode and a gate to which a charge transfer signal is applied;
a PNP-type bipolar transistor comprising a first end connected to a low power supply voltage and a base connected to a second end of the N-type charge transfer MOS transistor;
an N-type cell selection MOS transistor comprising a first end connected to a second end of the PNP-type charge amplification bipolar transistor and a gate to which a low selection signal is applied; and
an N-type reset MOS transistor comprising a first end connected to a power supply terminal providing a voltage equal to the low power supply voltage or a voltage equal to a combination of the low power supply voltage and a threshold voltage, a second end connected to a second end of the N-type cell selection MOS transistor, and a gate to which a reset signal is applied.

33. An active pixel sensor to receive an externally provided light signal and generate a current or a voltage signal corresponding to the received light signal, comprising:
a photo diode comprising an N-type electrode connected to a low power supply voltage and a P-type electrode developing an electrical charge in response to the received light signal;
a P-type charge transfer MOS transistor comprising a first end connected to the P-type electrode of the photo diode and a gate to which a charge transfer signal is applied;
an NPN-type charge amplification bipolar transistor comprising a first end connected to the low power supply voltage and a base connected to a second end of the P-type charge transfer MOS transistor;
a P-type cell selection MOS transistor comprising a first end connected to a second end of the NPN-type charge amplification bipolar transistor and a gate to which a low selection signal is applied; and
a P-type reset MOS transistor comprising a first end connected to a high power supply voltage, a second end connected to a second end of the P-type cell selection MOS transistor, and a gate to which a reset signal is applied.

34. The active pixel sensor of claim 33, wherein the N-type reset MOS transistor is an N-type depletion MOS transistor.
